(19) United States
(12) Patent Application Publication
(10) Pub. No.: US 2026/0066866 A1
(43) Pub. Date: Mar. 5, 2026

(54) FILTER

(71) Applicant: TDK Corporation, Tokyo (JP)

(72) Inventors: Yuta ASHIDA, Tokyo (JP); Keisuke YOSHIDA, Tokyo (JP); Takamasa YONEZAWA, Tokyo (JP); Tetsuzo GOTO, Tokyo (JP)

(73) Assignee: TDK Corporation, Tokyo (JP)

(21) Appl. No.: 19/284,756

(22) Filed: Jul. 30, 2025

(30) Foreign Application Priority Data
Aug. 27, 2024 (JP) 2024-145767

(51) Int. Cl. H03H 7/01; H03H 1/00

(52) U.S. Cl. CPC H03H 7/0115; H03H 1/00; H03H 2001/0085

(57) ABSTRACT

A filter includes a first ground conductor disposed at a position closer to a main surface in an element body, a second ground conductor disposed at a position closer to a main surface in the element body, and an inductor conductor and a capacitor conductor disposed in the element body. A third terminal electrode includes a first portion disposed on the main surface, a second portion disposed on the main surface, and a third portion disposed on a side surface and connecting the first portion and the second portion. The first ground conductor and the first portion of the third terminal electrode are electrically connected by connection conductors. The second ground conductor and the second portion of the third terminal electrode are electrically connected by connection conductors.

### CROSS-REFERENCE TO RELATED APPLICATION

This application is based upon and claims the benefit of priority from Japanese Patent Application No. 2024-145767, filed on Aug. 27, 2024, the entire contents of which are incorporated herein by reference.

### TECHNICAL FIELD

The present disclosure relates to a filter.

### BACKGROUND

For example, a filter described in Japanese Patent Application Laid-Open No. 2015-12323 is known. The filter described in Japanese Patent Application Laid-Open No. 2015-12323 includes a laminated body formed by laminating a plurality of insulator layers, a first terminal to a fourth terminal provided on the surface of the laminated body, a main line connected between the first terminal and the second terminal and provided on the insulator layer, a first sub-line connected to the third terminal and electromagnetically coupled to the main line, the first sub-line provided on the insulator layer, a second sub-line connected to the fourth terminal and electromagnetically coupled to the main line, the second sub-line provided on the insulator layer, and a ground conductor.

### SUMMARY

In the filter, the ground conductor is connected to the terminal disposed on the side surface of the laminated body by a flat plate-shaped connection portion (lead-out portion) exposed on the side surface of the laminated body. In this configuration, foreign matters such as moisture or water content may intrude into the laminated body through a gap in an interface between the laminated body and the connection portion, resulting in deterioration in the reliability of the filter.

An object of one aspect of the present disclosure is to provide a filter capable of suppressing deterioration in reliability.
(1) A filter according to one aspect of the present disclosure includes: an element body including a mounting surface and a main surface facing each other, and four side surfaces connecting the mounting surface and the main surface; a terminal electrode disposed on at least one of the four side surfaces, the terminal electrode being disposed over the mounting surface, the side surface, and the main surface; a first ground conductor disposed at a position closer to the main surface in the element body; a second ground conductor disposed at a position closer to the mounting surface in the element body; and an inductor conductor and a capacitor conductor disposed in the element body, wherein the terminal electrode includes a first portion disposed on the main surface, a second portion disposed on the mounting surface, and a third portion disposed on the side surface and connecting the first portion and the second portion, the first ground conductor and the first portion of the terminal electrode are electrically connected by a first connection conductor, the second ground conductor and the second portion of the terminal electrode are electrically connected by a second connection conductor, and each of the first connection conductor and the second connection conductor has a circular shape as viewed from a facing direction of the mounting surface and the main surface.

In the filter according to one disclosure of the present disclosure, the first connection conductor and the second connection conductor have a circular shape, and thus stress applied to each of the first connection conductor and the second connection conductor can be uniform. As a result, in the filter, the formation of a gap between the element body and the first and second connection conductors can be suppressed. Therefore, in the filter, the intrusion of foreign matters or the like into the element body can be suppressed, and thus deterioration in reliability can be suppressed.

In the filter, the terminal electrode is disposed over the mounting surface, the side surface, and the main surface, and thus stress can be dispersed as compared with, for example, a configuration (bottom surface terminal) in which the terminal electrode is disposed only on the mounting surface. Therefore, in the filter, stress applied to the first connection conductor and the second connection conductor connected to the terminal electrode can also be dispersed, and thus the formation of a gap between the element body and the first and second connection conductors can be suppressed. Therefore, in the filter, the intrusion of foreign matters or the like into the element body can be suppressed, and thus deterioration in reliability can be suppressed.
(2) In the filter of the above (1), at least one of the first connection conductor and the second connection conductor may be plurally provided. In this configuration, the terminal electrode and the first ground conductor and/or the second ground conductor are connected by the plurality of first connection conductors and/or second connection conductors. Therefore, there are a plurality of paths connecting the terminal electrode and the first ground conductor and/or the second ground conductor, and thus the ground can be strengthened.
(3) In the filter of any one of the above (1) and (2), one end of the inductor conductor may be electrically connected to the first ground conductor, and the other end of the inductor conductor may be electrically connected to the capacitor conductor.
(4) In the filter of the above (3), the second ground conductor and the capacitor conductor may be disposed to face each other in the facing direction of the mounting surface and the main surface, and constitute a capacitor.
(5) In the filter of the above (3) or (4), the inductor conductor may extend in the facing direction of the mounting surface and the main surface. In this configuration, the capacitor conductor is suspended from the inductor conductor. As a result, in the filter, a space is formed around the inductor conductor, and thus a region where a magnetic flux is generated can be secured around the inductor conductor, and a magnetic field can be formed around the inductor conductor. Therefore, in the filter, the apparent volume of the inductor can be increased. As a result, a Q-value can be improved in the filter.

According to one aspect of the present disclosure, deterioration in reliability can be suppressed.

### BRIEF DESCRIPTION OF THE DRAWINGS

FIG. 1 is a perspective view of a filter according to an embodiment;

FIG. 2 is a transparent perspective view of the filter illustrated in FIG. 1;

FIG. 3 is a view of the filter illustrated in FIG. 1 as viewed from a side of a side surface;

FIG. 4 is a view of the filter illustrated in FIG. 1 as viewed from a side of one end surface;

FIG. 5 is a view of the filter illustrated in FIG. 1 as viewed from a side of the other end surface;

FIG. 6 is an exploded perspective view of the filter;

FIG. 7 is a transparent perspective view of the filter illustrated in FIG. 1; and

FIG. 8 is an equivalent circuit diagram of the filter illustrated in FIG. 1.

### DETAILED DESCRIPTION

Hereinafter, preferred embodiments of the present invention will be described in detail with reference to the accompanying drawings. Note that the same or corresponding elements in the description of the drawings are denoted by the same reference signs, and redundant description is omitted.

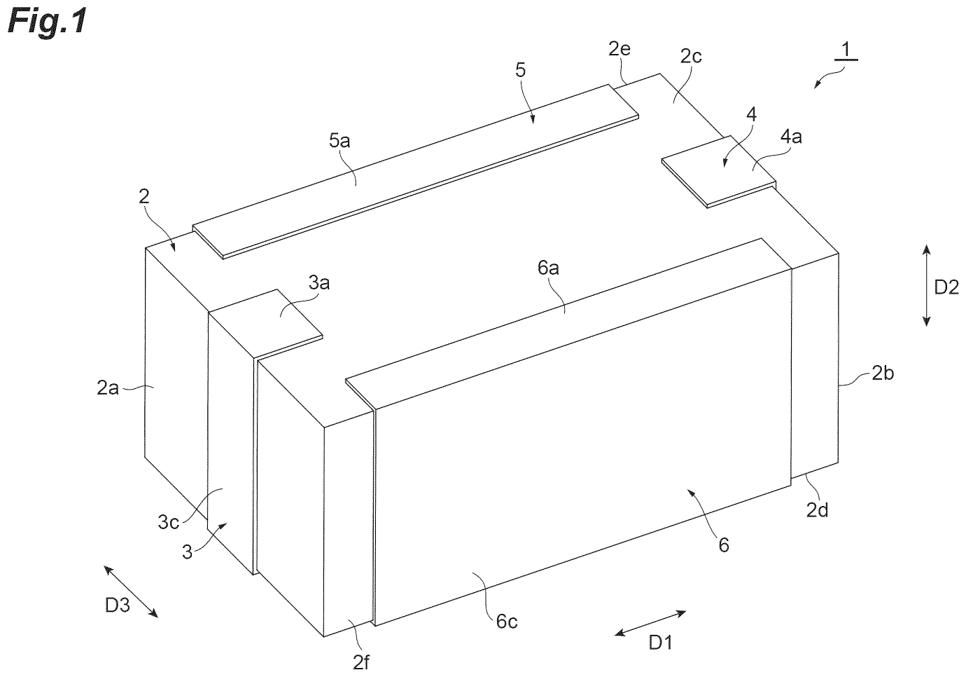

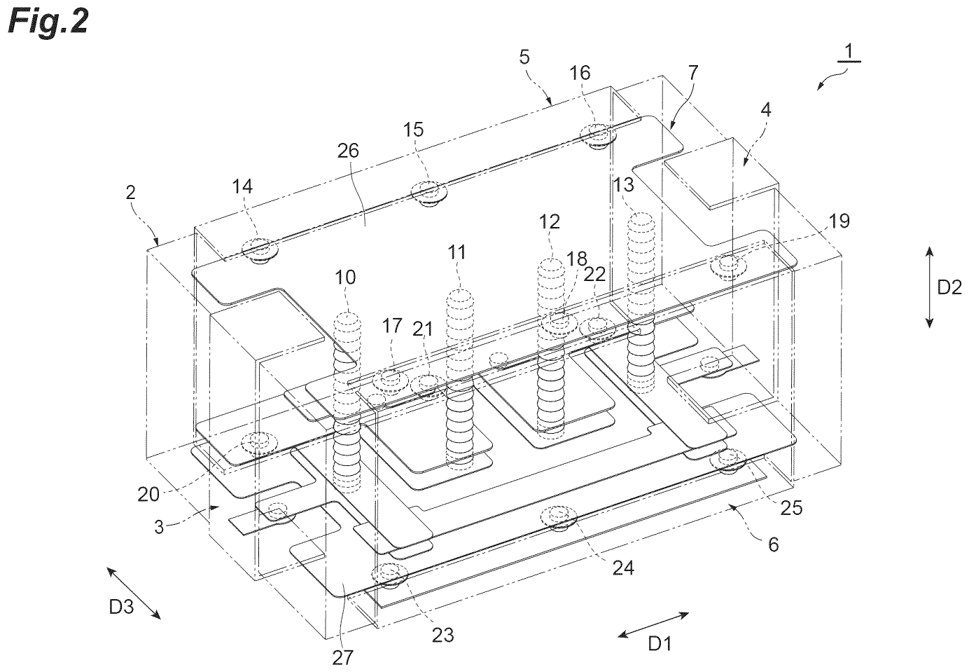

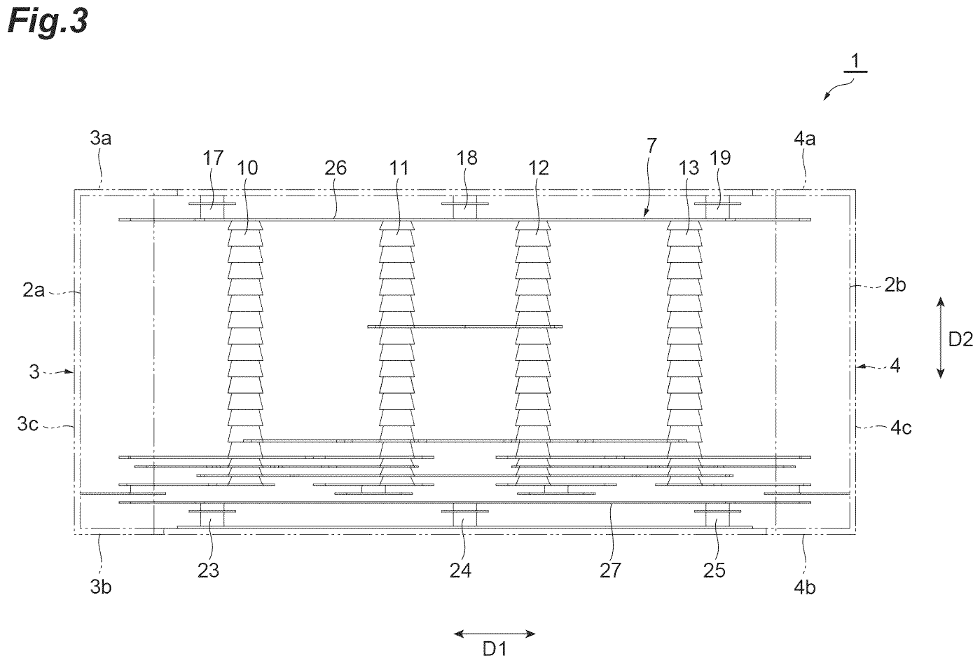

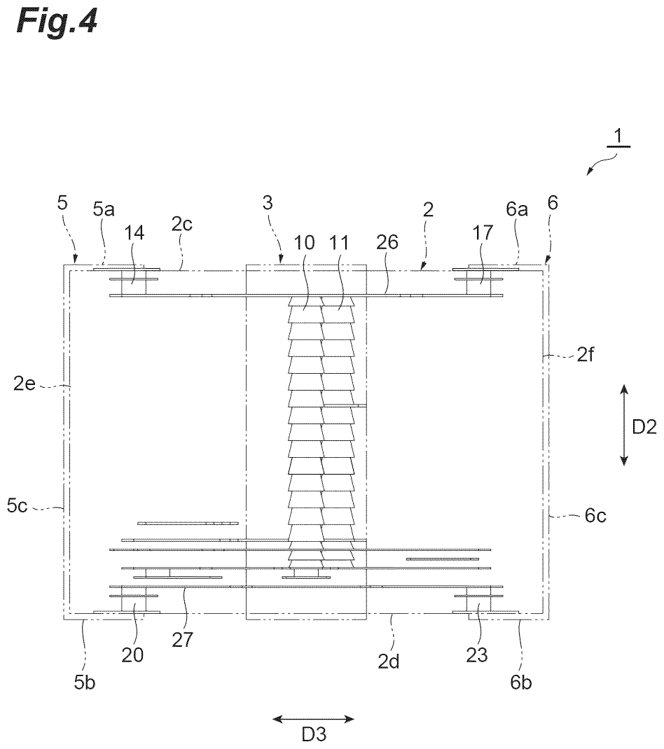

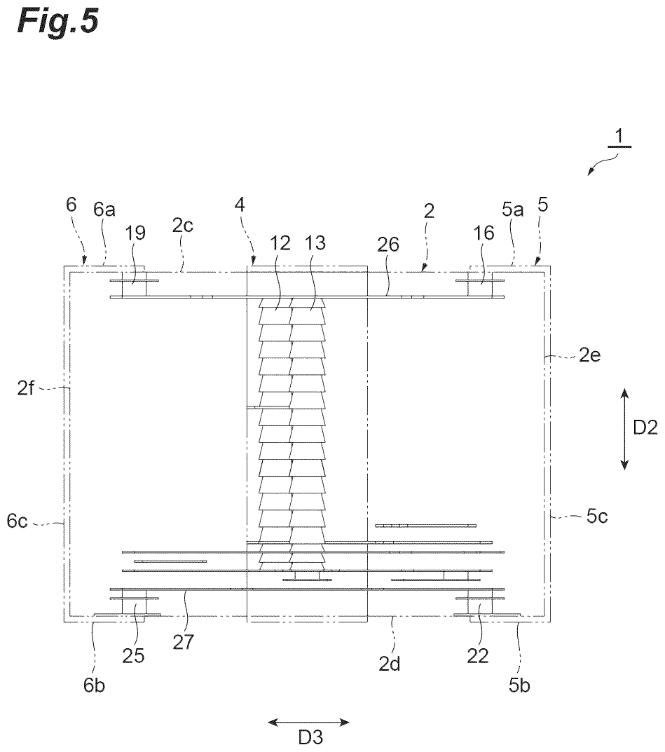

FIG. 1 is a perspective view of a filter according to an embodiment. FIG. 2 is a transparent perspective view of the filter illustrated in FIG. 1. FIG. 3 is a view of the filter illustrated in FIG. 1 as viewed from a side of a side surface. FIG. 4 is a view of the filter illustrated in FIG. 1 as viewed from a side of one end surface. FIG. 5 is a view of the filter illustrated in FIG. 1 as viewed from a side of the other end surface. As illustrated in FIGS. 1 to 5, a filter 1 includes an element body 2, a first terminal electrode 3, a second terminal electrode 4, a third terminal electrode 5, and a fourth terminal electrode 6, which are disposed on the element body 2, respectively, and a filter portion 7.

The element body 2 has a rectangular parallelepiped shape. The rectangular parallelepiped shape includes a rectangular parallelepiped shape in which corner portions and ridge line portions are chamfered, and a rectangular parallelepiped shape in which corner portions and ridge line portions are rounded. The element body 2 has, as the outer surfaces thereof, a pair of end surfaces (side surfaces) 2a and 2b facing each other, a pair of main surfaces 2c and 2d facing each other, and a pair of side surfaces 2e and 2f facing each other. A facing direction in which the pair of end surfaces 2a and 2b face each other is a first direction D1. A facing direction in which the pair of main surfaces 2c and 2d face each other is a second direction D2. A facing direction in which the pair of side surfaces 2e and 2f face each other is a third direction D3.

In the present embodiment, the first direction D1 is a longitudinal direction of the element body 2. The second direction D2 is a height direction of the element body 2, and is orthogonal to the first direction D1. The third direction D3 is a width direction of the element body 2, and is orthogonal to the second direction D2 and the first direction D1.

The pair of end surfaces 2a and 2b extend in the second direction D2 to connect the pair of main surfaces 2c and 2d. The pair of end surfaces 2a and 2b also extends in the third direction D3 (short side direction of the pair of main surfaces 2c and 2d). The pair of side surfaces 2e and 2f extend in the second direction D2 to connect the pair of main surfaces 2c and 2d. The pair of side surfaces 2e and 2f also extends in the first direction D1 (long side direction of the pair of end surfaces 2a and 2b). When the filter 1 is mounted on other electronic device (for example, a circuit board, a filter, or the like), the main surface 2d can be defined as a mounting surface facing the other electronic device.

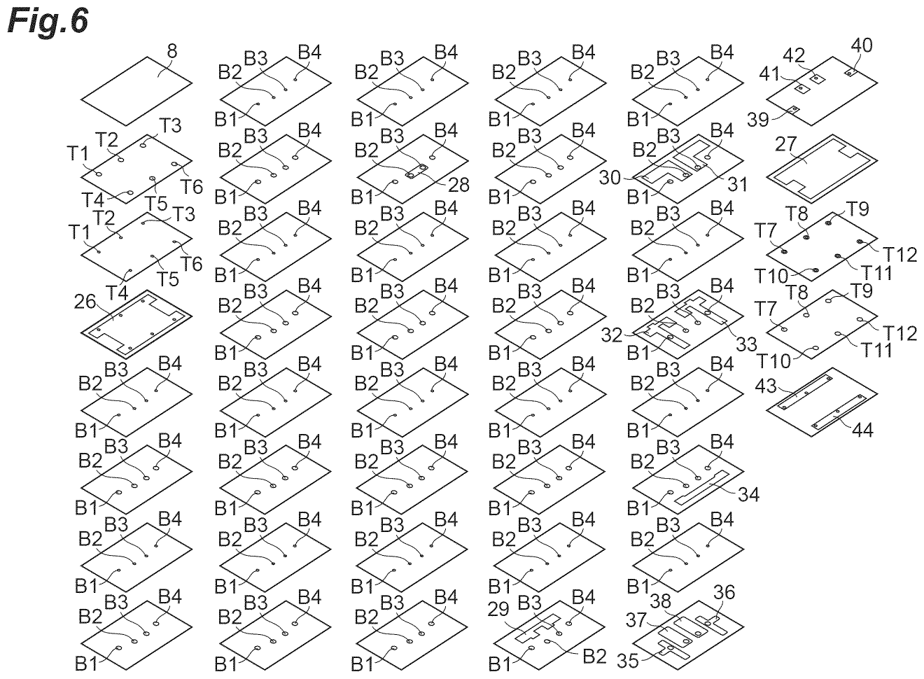

The element body 2 is configured by laminating a plurality of dielectric layers 8 (see FIG. 6). Each dielectric layer is laminated in the second direction D2. That is, the second direction D2 is a laminating direction. The element body 2 includes the plurality of laminated dielectric layers. Each dielectric layer 8 is composed of, for example, a sintered body of a ceramic green sheet containing a dielectric material (dielectric ceramic such as BaTiO₃-based, Ba(Ti, Zr)O₃-based, or (Ba, Ca)TiO₃-based). In the actual element body 2, the plurality of dielectric layers 8 are integrated to such an extent that boundaries between the layers cannot be visually recognized.

The first terminal electrode 3 is disposed on a side of the end surface 2a of the element body 2. The first terminal electrode 3 is disposed at the center of the end surface 2a in the third direction D3. The first terminal electrode 3 is formed so as to cover a part of the end surface 2a along the second direction D2 of the element body 2, and is formed on a part of the main surface 2c and a part of the main surface 2d. The first terminal electrode 3 includes a first portion 3a, a second portion 3b, and a third portion 3c. The first portion 3a, the second portion 3b, and the third portion 3c are integrally formed. The first portion 3a is disposed on the main surface 2c. The second portion 3b is disposed on the main surface 2d. The third portion 3c is disposed on the end surface 2a. The third portion 3c extends along the second direction D2 and electrically connects the first portion 3a and the second portion 3b.

The second terminal electrode 4 is disposed on a side of the end surface 2b of the element body 2. The second terminal electrode 4 is disposed at the center of the end surface 2b in the third direction D3. The second terminal electrode 4 is formed so as to cover a part of the end surface 2b along the second direction D2 of the element body 2, and is formed on a part of the main surface 2c and a part of the main surface 2d. The second terminal electrode 4 includes a first portion 4a, a second portion 4b, and a third portion 4c. The first portion 4a, the second portion 4b, and the third portion 4c are integrally formed. The first portion 4a is disposed on the main surface 2c. The second portion 4b is disposed on the main surface 2d. The third portion 4c is disposed on the end surface 2b. The third portion 4c extends along the second direction D2 and electrically connects the first portion 4a and the second portion 4b.

The third terminal electrode 5 is disposed on a side of the side surface 2e of the element body 2. The third terminal electrode 5 is formed so as to cover a part of the side surface 2e along the second direction D2 of the element body 2, and is formed on a part of the main surface 2c and a part of the main surface 2d. The third terminal electrode 5 includes a first portion 5a, a second portion 5b, and a third portion 5c. The first portion 5a, the second portion 5b, and the third portion 5c are integrally formed. The first portion 5a is disposed on the main surface 2c. The first portion 5a extends along the first direction D1. The second portion 5b is disposed on the main surface 2d. The second portion 5b extends along the first direction D1. The third portion 5c is disposed on the side surface 2e. The third portion 5c extends along the second direction D2 and electrically connects the first portion 5a and the second portion 5b.

The fourth terminal electrode 6 is disposed on a side of the side surface 2f of the element body 2. The fourth terminal electrode 6 is formed so as to cover a part of the side surface 2f along the second direction D2 of the element body 2, and is formed on a part of the main surface 2c and a part of the main surface 2d. The fourth terminal electrode 6 includes a first portion 6a, a second portion 6b, and a third portion 6c. The first portion 6a, the second portion 6b, and the third portion 6c are integrally formed. The first portion 6a is disposed on the main surface 2c. The first portion 6a extends along the first direction D1. The second portion 6b is disposed on the main surface 2d. The second portion 6b extends along the first direction D1. The third portion 6c is disposed on the side surface 2f. The third portion 6c extends along the second direction D2 and electrically connects the first portion 6a and the second portion 6b.

The first terminal electrode 3, the second terminal electrode 4, the third terminal electrode 5, and the fourth terminal electrode 6 contain a conductive material (for example, Ag or Pd or the like). The first terminal electrode 3, the second terminal electrode 4, the third terminal electrode 5, and the fourth terminal electrode 6 are configured as a sintered body of a conductive paste containing a conductive material (for example, Ag powder or Pd powder or the like). A plating layer may be formed on the surfaces of the first terminal electrode 3, the second terminal electrode 4, the third terminal electrode 5, and the fourth terminal electrode 6. The plating layer is formed through, for example, electroplating. The plating layer has a layer structure including a Cu plating layer, an Ni plating layer, and an Sn plating layer, or a layer structure including an Ni plating layer and an Sn plating layer, or the like.

The first terminal electrode 3 constitutes an input terminal (a terminal to which a signal is input). The second terminal electrode 4 constitutes an output terminal (a terminal to which a signal is output). The third terminal electrode 5 constitutes a ground terminal (a terminal connected to the ground). The fourth terminal electrode 6 constitutes a ground terminal.

FIG. 6 is an exploded perspective view of the filter 1. As illustrated in FIGS. 1 to 6, the filter portion 7 includes a first inductor conductor 10, a second inductor conductor 11, a third inductor conductor 13, a fourth inductor conductor 12, a connection conductor (first connection conductor) 14, a connection conductor (first connection conductor) 15, a connection conductor (first connection conductor) 16, a connection conductor (first connection conductor) 17, a connection conductor (first connection conductor) 18, a connection conductor (first connection conductor) 19, a connection conductor (second connection conductor) 20, a connection conductor (second connection conductor) 21, a connection conductor (second connection conductor) 22, a connection conductor (second connection conductor) 23, a connection conductor (second connection conductor) 24, a connection conductor (second connection conductor) 25, a first ground conductor 26, a second ground conductor 27, a connection conductor 28, a capacitor conductor 29, a capacitor conductor 30, a capacitor conductor 31, a capacitor conductor 32, a capacitor conductor 33, a capacitor conductor 34, a capacitor conductor 35, a capacitor conductor 36, a capacitor conductor 37, a capacitor conductor 38, a connection conductor 39, a connection conductor 40, a capacitor conductor 41, a capacitor conductor 42, a connection conductor 43, and a connection conductor 44.

Each conductor may contain a conductive material (for example, Ag or Pd or the like). Each conductor may be configured as a sintered body of a conductive paste containing a conductive material (for example, Ag powder or Pd powder or the like).

The first inductor conductor 10 extends along the second direction D2. The first inductor conductor 10 can include a plurality of via conductors B1. The first inductor conductor 10 is disposed at a position closer to the end surface 2a in the first direction D1 at a central position in the third direction D3. The first inductor conductor 10 electrically connects the first ground conductor 26 to the capacitor conductor 32 and the capacitor conductor 35. One end (end on a side of the main surface 2c) of the first inductor conductor 10 is connected to the first ground conductor 26. The other end (end on a side of the main surface 2d) of the first inductor conductor 10 is connected to the capacitor conductor 32 and the capacitor conductor 35.

The second inductor conductor 11 extends along the second direction D2. The second inductor conductor 11 can include a plurality of via conductors B2. The second inductor conductor 11 is disposed at a position closer to the side surface 2f than the first inductor conductor 10 in the third direction D3. The second inductor conductor 11 is disposed at a position closer to the center than the first inductor conductor 10 in the first direction D1. The second inductor conductor 11 electrically connects the first ground conductor 26 to the capacitor conductor 30 and the capacitor conductor 37. One end (end on a side of the main surface 2c) of the second inductor conductor 11 is connected to the first ground conductor 26. The other end (end on a side of the main surface 2d) of the second inductor conductor 11 is connected to the capacitor conductor 30 and the capacitor conductor 37.

The third inductor conductor 13 extends along the second direction D2. The third inductor conductor 13 can include a plurality of via conductors B3. The third inductor conductor 13 is disposed at a position closer to the end surface 2b in the first direction D1 at a central position in the third direction D3. The third inductor conductor 13 electrically connects the first ground conductor 26 to the capacitor conductor 33 and the capacitor conductor 36. One end (end on a side of the main surface 2c) of the third inductor conductor 13 is connected to the first ground conductor 26. The other end (end on a side of the main surface 2d) of the third inductor conductor 13 is connected to the capacitor conductor 33 and the capacitor conductor 36.

The fourth inductor conductor 12 extends along the second direction D2. The fourth inductor conductor 12 can include a plurality of via conductors B4. The fourth inductor conductor 12 is disposed at a position closer to the side surface 2f than the third inductor conductor 13 in the third direction D3. The fourth inductor conductor 12 is disposed at a position closer to the center than the third inductor conductor 13 in the first direction D1. The fourth inductor conductor 12 electrically connects the first ground conductor 26 to the capacitor conductor 31 and the capacitor conductor 38. One end (end on a side of the main surface 2c) of the fourth inductor conductor 12 is connected to the first ground conductor 26. The other end (end on a side of the main surface 2d) of the fourth inductor conductor 12 is connected to the capacitor conductor 31 and the capacitor conductor 38.

The connection conductor 14 electrically connects the first portion 5a of the third terminal electrode 5 and the first ground conductor 26. The connection conductor 14 can be configured by a through-hole conductor T1. The connection conductor 14 is disposed at a position closer to the end surface 2a in the first direction D1.

The connection conductor 15 electrically connects the first portion 5a of the third terminal electrode 5 and the first ground conductor 26. The connection conductor 15 can be configured by a through-hole conductor T2. The connection conductor 15 is disposed at a central position in the first direction D1.

The connection conductor 16 electrically connects the first portion 5a of the third terminal electrode 5 and the first ground conductor 26. The connection conductor 16 can be configured by a through-hole conductor T3. The connection conductor 16 is disposed at a position closer to the end surface 2b in the first direction D1. The connection conductor 14, the connection conductor 15, and the connection conductor 16 are disposed at predetermined intervals in the first direction D1.

The connection conductor 17 electrically connects the first portion 6a of the fourth terminal electrode 6 and the first ground conductor 26. The connection conductor 17 can be configured by a through-hole conductor T4. The connection conductor 17 is disposed at a position closer to the end surface 2a in the first direction D1.

The connection conductor 18 electrically connects the first portion 6a of the fourth terminal electrode 6 and the first ground conductor 26. The connection conductor 18 can be configured by a through-hole conductor T5. The connection conductor 18 is disposed at a central position in the first direction D1.

The connection conductor 19 electrically connects the first portion 6a of the fourth terminal electrode 6 and the first ground conductor 26. The connection conductor 19 can be configured by a through-hole conductor T6. The connection conductor 19 is disposed at a position closer to the end surface 2b in the first direction D1. The connection conductor 17, the connection conductor 18, and the connection conductor 19 are disposed at predetermined intervals in the first direction D1.

The connection conductor 20 electrically connects the second portion 5b of the third terminal electrode 5 and the second ground conductor 27. The connection conductor 20 can be configured by a through-hole conductor T7. The connection conductor 20 is disposed at a position closer to the end surface 2a in the first direction D1.

The connection conductor 21 electrically connects the second portion 5b of the third terminal electrode 5 and the second ground conductor 27. The connection conductor 21 can be configured by a through-hole conductor T8. The connection conductor 21 is disposed at a central position in the first direction D1.

The connection conductor 22 electrically connects the second portion 5b of the third terminal electrode 5 and the second ground conductor 27. The connection conductor 22 can be configured by a through-hole conductor T9. The connection conductor 22 is disposed at a position closer to the end surface 2b in the first direction D1. The connection conductor 20, the connection conductor 21, and the connection conductor 22 are disposed at predetermined intervals in the first direction D1.

The connection conductor 23 electrically connects the second portion 6b of the fourth terminal electrode 6 and the second ground conductor 27. The connection conductor 23 can be configured by a through-hole conductor T10. The connection conductor 23 is disposed at a position closer to the end surface 2a in the first direction D1.

The connection conductor 24 electrically connects the second portion 6b of the fourth terminal electrode 6 and the second ground conductor 27. The connection conductor 24 can be configured by a through-hole conductor T11. The connection conductor 24 is disposed at a central position in the first direction D1.

The connection conductor 25 electrically connects the second portion 6b of the fourth terminal electrode 6 and the second ground conductor 27. The connection conductor 25 can be configured by a through-hole conductor T12. The connection conductor 25 is disposed at a position closer to the end surface 2b in the first direction D1. The connection conductor 23, the connection conductor 24, and the connection conductor 25 are disposed at predetermined intervals in the first direction D1.

The connection conductors 14 to 25 exhibit a circular shape as viewed from the second direction D2. The connection conductors 14 to 25 extend in a columnar shape in the second direction D2.

The first ground conductor 26 is disposed at a position close to the main surface 2c. The first ground conductor 26 is electrically connected to the third terminal electrode 5 (first portion 5a) by the connection conductor 14, the connection conductor 15, and the connection conductor 16. The first ground conductor 26 is electrically connected to the fourth terminal electrode 6 (first portion 6a) by the connection conductor 17, the connection conductor 18, and the connection conductor 19.

The second ground conductor 27 is disposed at a position closer to the main surface 2d. The second ground conductor 27 is electrically connected to the third terminal electrode 5 (second portion 5b) by the connection conductor 20, the connection conductor 21, and the connection conductor 22. The second ground conductor 27 is electrically connected to the fourth terminal electrode 6 (second portion 6b) by the connection conductor 23, the connection conductor 24, and the connection conductor 25.

The connection conductor 28 electrically connects the second inductor conductor 11 and the fourth inductor conductor 12. The capacitor conductor 29 is disposed at a position facing each of the capacitor conductor 30 and the capacitor conductor 31. The capacitor conductor 30 is connected to the second inductor conductor 11. The capacitor conductor 31 is connected to the fourth inductor conductor 12.

The capacitor conductor 32 is connected to the first inductor conductor 10. The capacitor conductor 33 is connected to the third inductor conductor 13. The capacitor conductor 34 is disposed at a position facing each of the capacitor conductor 32 and the capacitor conductor 33. The capacitor conductor 35 is connected to the first inductor conductor 10. The capacitor conductor 36 is connected to the third inductor conductor 13. The capacitor conductor 37 is connected to the second inductor conductor 11. The capacitor conductor 38 is connected to the fourth inductor conductor 12.

The connection conductor 39 is electrically connected to the capacitor conductor 35. The connection conductor 39 is exposed on the end surface 2a and connected to the first terminal electrode 3. The connection conductor 40 is electrically connected to the capacitor conductor 36. The connection conductor 40 is exposed on the end surface 2b and connected to the second terminal electrode 4.

The capacitor conductor 41 is electrically connected to the capacitor conductor 37. The capacitor conductor 41 is disposed at a position facing the second ground conductor 27. The capacitor conductor 42 is electrically connected to the capacitor conductor 38. The capacitor conductor 42 is disposed at a position facing the second ground conductor 27.

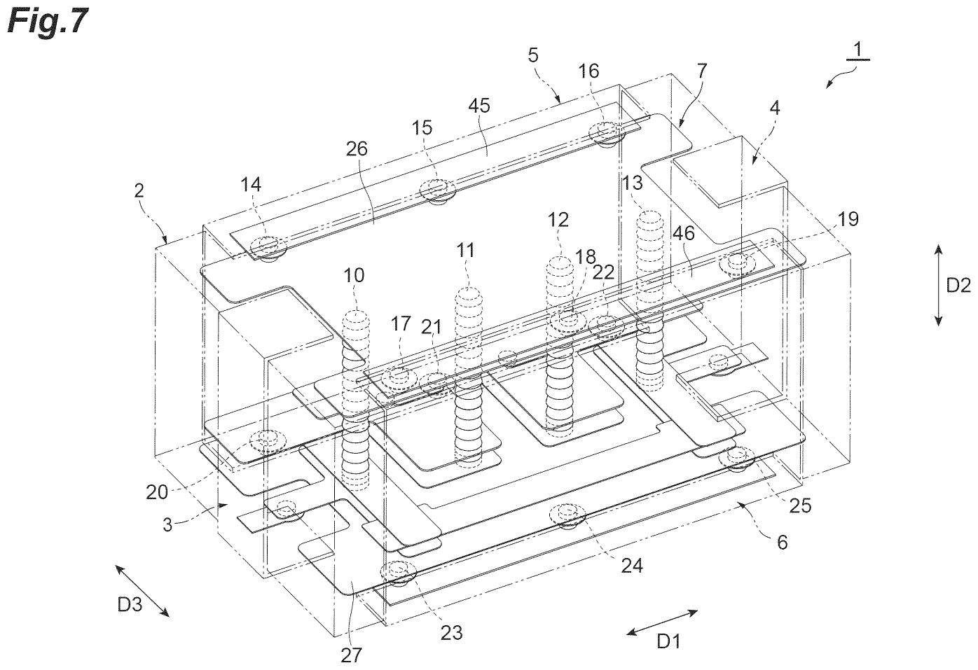

FIG. 7 is a transparent perspective view of the filter illustrated in FIG. 1. In the filter 1 illustrated in FIG. 7, a pad 45 and a pad 46 are illustrated. The pad 45 and the pad 46 contain a conductive material (for example, Ag or Pd or the like).

The pad 45 is disposed between the third terminal electrode 5 and the main surface 2c of the element body 2. The pad 45 is provided so as to cover the connection conductors 14 to 16. The connection conductors 14 to 16 are connected to the third terminal electrode 5 via the pad 45. In the actual filter 1, the pad 45 is integrated by firing to such an extent that the boundary with the third terminal electrode 5 cannot be visually recognized.

The pad 46 is disposed between the fourth terminal electrode 6 and the main surface 2c of the element body 2. The pad 45 and the pad 46 are formed on the dielectric layer 8. The pad 46 is provided so as to cover the connection conductors 17 to 19. The connection conductors 17 to 19 are connected to the fourth terminal electrode 6 via the pad 46. In the actual filter 1, the pad 46 is integrated by firing to such an extent that the boundary with the fourth terminal electrode 6 cannot be visually recognized.

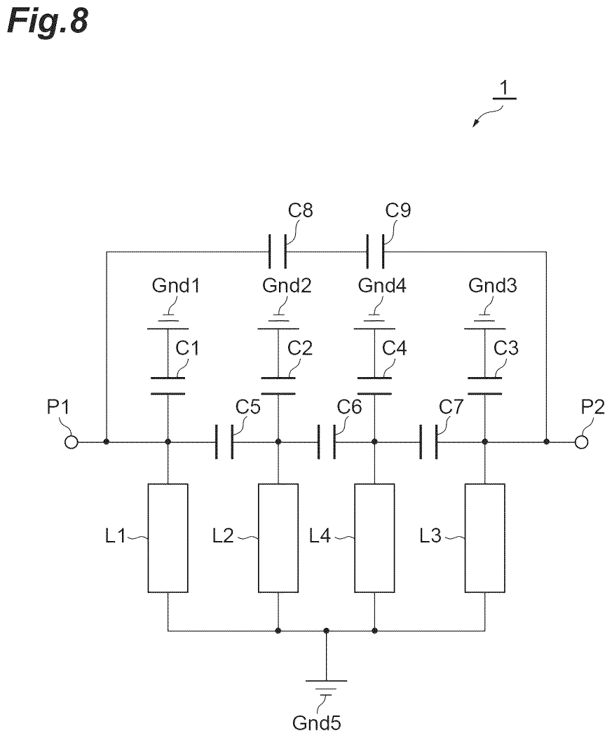

FIG. 8 is an equivalent circuit diagram of the filter 1 illustrated in FIG. 1. As illustrated in FIG. 8, the filter 1 includes an input port P1, an output port P2, a ground Gnd1, a ground Gnd2, a ground Gnd3, a ground Gnd4, a ground Gnd5, an inductor L1, an inductor L2, an inductor L3, an inductor L4, a capacitor C1, a capacitor C2, a capacitor C3, a capacitor C4, a capacitor C5, a capacitor C6, a capacitor C7, a capacitor C8, and a capacitor C9.

The input port P1 includes the first terminal electrode 3. The output port P2 includes the second terminal electrode 4. The ground Gnd1, the ground Gnd2, the ground Gnd3, the ground Gnd4, and the ground Gnd5 include the third terminal electrode 5 and the fourth terminal electrode 6.

The inductor L1 includes the first inductor conductor 10. The inductor L2 includes the second inductor conductor 11. The inductor L3 includes the third inductor conductor 13. The inductor L4 includes the fourth inductor conductor 12.

The capacitor C1 includes the second ground conductor 27 and the capacitor conductor 35. The capacitor C2 includes the second ground conductor 27 and the capacitor conductor 41. The capacitor C3 includes the second ground conductor 27 and the capacitor conductor 36. The capacitor C4 includes the second ground conductor 27 and the capacitor conductor 42.

The capacitor C5 includes the capacitor conductor 30 and the capacitor conductor 32. The capacitor C6 includes the capacitor conductor 29, the capacitor conductor 30, and the capacitor conductor 31. The capacitor C7 includes the capacitor conductor 31 and the capacitor conductor 33.

The capacitor C8 includes the capacitor conductor 34 and the capacitor conductor 35. The capacitor C9 includes the capacitor conductor 34 and the capacitor conductor 36.

As described above, in the filter 1 according to the present embodiment, the connection conductors 14 to 25 have a circular shape, and thus stress applied to each of the connection conductors 14 to 25 can be uniform. As a result, in the filter 1, the formation of a gap between the element body 2 and the connection conductors 14 to 25 can be suppressed. Therefore, in the filter 1, the intrusion of foreign matters or the like into the element body 2 can be suppressed, and thus deterioration in reliability can be suppressed.

In the filter 1 according to the present embodiment, the third terminal electrode 5 is formed so as to cover a part of the side surface 2e along the second direction D2 of the element body 2, and is formed on a part of the main surface 2c and a part of the main surface 2d. In this configuration, the third terminal electrode 5 is disposed over the main surface 2c, the side surface 2e, and the main surface 2d, and thus stress can be dispersed as compared with, for example, a configuration (bottom surface terminal) in which the terminal electrode is disposed only on the main surface 2d (mounting surface). Therefore, in the filter 1, stress applied to the connection conductors 14 to 16 and the connection conductors 20 to 22 connected to the third terminal electrode 5 can also be dispersed, and thus the formation of a gap between the element body 2 and the connection conductors 14 to 16 and 20 to 22 can be suppressed. Therefore, in the filter 1, the intrusion of foreign matters or the like into the element body 2 can be suppressed, and thus deterioration in reliability can be suppressed. The same applies to the fourth terminal electrode 6.

In the filter 1 according to the present embodiment, the third terminal electrode 5, the first ground conductor 26, and the second ground conductor 27 are connected by the connection conductors 14 to 16 and 20 to 22. As described above, by connecting the third terminal electrode 5 to the first ground conductor 26 and the second ground conductor 27 on the main surface 2c and the main surface 2d, it is possible to reduce the risk of peeling the dielectric layer 8. In particular, in the configuration in which the terminal electrode and the ground conductor are connected by the plurality of connection conductors (connecting portion, lead-out portion) exposed on the side surfaces 2e and 2f, the risk of peeling from the interface between the element body and the connection conductor may be high. Meanwhile, in the filter 1, the third terminal electrode 5 is connected to the first ground conductor 26 and the second ground conductor 27 on the main surface 2c and the main surface 2d, and thus the peeling of the dielectric layer 8 can be suppressed.

In the filter 1 according to the present embodiment, the third terminal electrode 5 is electrically connected to the first ground conductor 26 by the plurality of connection conductors 14 to 16, and is electrically connected to the second ground conductor 27 by the plurality of connection conductors 20 to 22. Therefore, in the filter 1, there are a plurality of paths connecting the third terminal electrode 5 to the first ground conductor 26 and the second ground conductor 27, and thus the ground can be strengthened. In the filter 1, the fourth terminal electrode 6 is electrically connected to the first ground conductor 26 by the plurality of connection conductors 17 to 19, and is electrically connected to the second ground conductor 27 by the plurality of connection conductors 23 to 25. Therefore, in the filter 1, there are a plurality of paths connecting the fourth terminal electrode 6 to the first ground conductor 26 and the second ground conductor 27, and thus the ground can be strengthened.

In the filter 1 according to the present embodiment, the first inductor conductor 10, the second inductor conductor 11, the third inductor conductor 13, and the fourth inductor conductor 12 extend in the second direction D2. In this configuration, the capacitor conductor 30, the capacitor conductor 31, the capacitor conductor 32, and the capacitor conductor 33 are suspended from the first inductor conductor 10, the second inductor conductor 11, the third inductor conductor 13, and the fourth inductor conductor 12. As a result, in the filter 1, a space is formed around the first inductor conductor 10, the second inductor conductor 11, the third inductor conductor 13, and the fourth inductor conductor 12, and thus a region where a magnetic flux is generated can be secured around the first inductor conductor 10, the second inductor conductor 11, the third inductor conductor 13, and the fourth inductor conductor 12, and a magnetic field can be formed around the first inductor conductor 10, the second inductor conductor 11, the third inductor conductor 13, and the fourth inductor conductor 12. Therefore, in the filter 1, the apparent volume of the inductor can be increased. As a result, a Q-value can be improved in the filter.

In the filter 1 according to the present embodiment, the pad 45 and the pad 46 are provided before firing. The pad 45 is provided so as to cover the connection conductors 14 to 16. The pad 46 is provided so as to cover the connection conductors 17 to 19. In this configuration, the mixing of foreign matters and the like into the element body 2 via the connection conductors 14 to 19 in a process before firing can be suppressed.

Although the embodiment of the present disclosure has been described above, the present disclosure is not necessarily limited to the above-described embodiment, and various modifications can be made without departing from the gist thereof.

In the above embodiment, a mode in which the first portion 5a of the third terminal electrode 5 and the first ground conductor 26 are connected by the three connection conductors, that is, the connection conductor 14, the connection conductor 15, and the connection conductor 16 has been described as an example. However, the first portion 5a of the third terminal electrode 5 and the first ground conductor 26 may be connected by one or two connection conductors, or may be connected by four or more connection conductors. The same applies to the connection conductors 17 to 25.

In the above embodiment, the configuration in which the first inductor conductor 10, the second inductor conductor 11, the third inductor conductor 13, and the fourth inductor conductor 12 extend linearly along the second direction D2 has been described as an example. However, the first inductor conductor 10, the second inductor conductor 11, the third inductor conductor 13, and the fourth inductor conductor 12 are not limited to a linear shape, and various aspects can be adopted.

What is claimed is:

1. A filter comprising:
an element body including a mounting surface and a main surface facing each other, and four side surfaces connecting the mounting surface and the main surface;
a terminal electrode disposed on at least one of the four side surfaces, the terminal electrode being disposed over the mounting surface, the side surface, and the main surface;
a first ground conductor disposed at a position closer to the main surface in the element body;
a second ground conductor disposed at a position closer to the mounting surface in the element body; and
an inductor conductor and a capacitor conductor disposed in the element body, wherein
the terminal electrode includes a first portion disposed on the main surface, a second portion disposed on the mounting surface, and a third portion disposed on the side surface and connecting the first portion and the second portion,
the first ground conductor and the first portion of the terminal electrode are electrically connected by a first connection conductor,
the second ground conductor and the second portion of the terminal electrode are electrically connected by a second connection conductor, and
each of the first connection conductor and the second connection conductor has a circular shape as viewed from a facing direction of the mounting surface and the main surface.

2. The filter according to claim 1, wherein at least one of the first connection conductor and the second connection conductor is plurally provided.

3. The filter according to claim 1, wherein
one end of the inductor conductor is electrically connected to the first ground conductor, and
the other end of the inductor conductor is electrically connected to the capacitor conductor.

4. The filter according to claim 3, wherein the second ground conductor and the capacitor conductor are disposed to face each other in the facing direction of the mounting surface and the main surface, and constitute a capacitor.

5. The filter according to claim 3, wherein the inductor conductor extends in the facing direction of the mounting surface and the main surface.
